(19) United States
(12) Patent Application Publication
(10) Pub. No.: US 2006/0252264 A1
(43) Pub. Date: Nov. 9, 2006

(54) Semiconductor device and manufacturing method thereof

(75) Inventors: Naohiko Kimizuka, Kawasaki (JP); Kiyotaka Imai, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, Kawasaki (JP)

(21) Appl. No.: 11/416,209

(22) Filed: May 3, 2006

(30) Foreign Application Priority Data
May 6, 2005 (JP) 2005-135188

(51) Int. Cl. H01L 21/44; H01L 23/48

(52) U.S. Cl. 438/682; 257/757

(57) ABSTRACT

A semiconductor device includes: a semiconductor substrate; a semiconductor element formed on the semiconductor substrate and containing a gate electrode; impurity diffusion layers formed at both sides, in a cross-section in a gate length direction of the gate electrode, of a region on which the semiconductor element is formed of the semiconductor substrate; first silicide films formed respectively at the surface of the impurity diffusion layers, composed of a silicide compound of a first metal; and a second silicide film, formed at least at the surface of the gate electrode, composed of a silicide compound of a second metal different to the first metal. The silicide compound of the second metal has a silicidation temperature lower than the silicidation temperature of the silicide compound of the first metal.

This application is based on Japanese patent application NO. 2005-135188, the content of which is incorporated hereinto by reference.

### BACKGROUND

1. Technical Field

The present invention relates to a semiconductor device in which a silicide film is formed at a gate electrode and impurity diffusion layers and manufacturing method thereof.

2. Related Art

Technology by which the surface of a gate electrode of a transistor constructed from polysilicon or the surface of an impurity diffusion layer constituting source region or drain region of a transistor is silicided for realizing low resistance of these regions is well-known. It is possible to make operation of a transistor high-speed by making components of the transistor low resistance.

Conventionally, siliciding is carried out by forming a silicide film at the same time on the gate electrode surface and the impurity diffusion layer surface after forming a gate insulation film, gate electrode, sidewall insulation film and impurity diffusion layer of a transistor, by forming a metal layer on polysilicon of the gate electrode and on the impurity diffusion layer and subjecting this to heat treatment.

However, the appropriate conditions for siliciding the gate electrode and the impurity diffusion layer are different. By then forming these at the same time, there may be problems with, for example, crystal defects and abnormal growth occurring at the impurity diffusion layer.

The following method for manufacturing a semiconductor device is disclosed in Japanese Laid-open patent publication NO. 2004-273556. In the first siliciding, a silicide film is formed on a diffusion layer, and a dummy silicide film is formed on a gate. After depositing a first inter-layer insulation film, the first inter-layer insulation film and the dummy silicide film are removed by planarization using CMP to make the first inter-layer insulation film and a polysilicon electrode flat. After this, a Co film is deposited, heat treatment is performed, and a silicide film is formed through siliciding of the upper section of a polysilicon electrode. It is disclosed that in this way, it is possible to form a silicide film on the impurity diffusion layer and the silicide film on the upper part of the gate under different conditions, with appropriate adjustment of characteristics of the gate upper section silicide film and the silicide film on the diffusion layer.

However, in the method described in Japanese Laid-open patent publication NO. 2004-273556, heat treatment at a high-temperature is carried out while forming the silicide film on the upper part of the gate. There are therefore problems such as abnormal growth of the silicide film formed at the impurity diffusion layer or the occurrence of coagulation that divides grains. Problems therefore occur such as the impurity diffusion layer being of high-resistance or of bonding leakage increasing, etc.

### SUMMARY OF THE INVENTION

According to the present invention, there is provided a semiconductor device including: a semiconductor substrate; a semiconductor element formed on the semiconductor substrate and containing a gate electrode; impurity diffusion layers formed at both sides, in a cross-section in a gate length direction of the gate electrode, of a region on which the semiconductor element is formed of the semiconductor substrate; first silicide films formed respectively at the surface of the impurity diffusion layers, composed of a silicide compound of a first metal; and a second silicide film, formed at least at the surface of the gate electrode, composed of a silicide compound of a second metal different to the first metal, wherein the silicide compound of the second metal has a silicidation temperature lower than the silicidation temperature of the silicide compound of the first metal.

The combination of the first metal and the second metal may be, in order, nickel and palladium, cobalt and palladium, or cobalt and nickel. The silicidation temperatures of the cobalt silicide compound (CoSi₂), nickel silicide compound (NiSi), and palladium silicide compound (Pd₂Si) are of high temperatures in this order (Kusano, “Semiconductor Encyclopedia”, Kogyo Chosakai Publishing, Dec. 20th, 1999, P 521; Sano, The 52nd Lecture of the Japan Society of Applied Physics, Lecture Proceedings (spring 2005), P 958; and S. S. Lau et al, Interactins in the Co/Si thin-film system. I. Kinetics, J. appl. Phys. 49(7), July 1978, pp 4005-4010.) In the event that the second metal is nickel, the silicide compound of the second metal can be composed taking NiSi as a main component. However, in this case also, the silicide compound of the second metal may contain NiSi₂.

In this way, the second silicide film of the gate electrode can be configured from a silicide compound of the second metal that is of a silicidation temperature that is lower than that of the silicide compound of the first metal. Therefore, for example, after forming a first silicide film on the surface of the impurity diffusion layers, in the event that the second silicide film is formed in a separate step, it is possible to form the second silicide film using a lower temperature. Because of this, it is possible to prevent abnormal growth and coagulation of the first silicide film during forming of the second silicide film of the gate electrode after forming the first silicide film. As a result, it is possible to prevent high resistance of the impurity diffusion layers of the semiconductor device and increases in junction leakage.

According to the present invention, there is provided a semiconductor device including: a semiconductor substrate; a semiconductor element formed on the semiconductor substrate and containing a gate electrode; impurity diffusion layers formed at both sides, in a cross-section in a gate length direction of the gate electrode, of a region on which the semiconductor element is formed of the semiconductor substrate; first silicide films formed respectively at the surface of the impurity diffusion layers, composed of a silicide compound of a first metal; and a second silicide film, formed at least at the surface of the gate electrode, composed of a silicide compound of a second metal different to the first metal, wherein the silicide compound of the second metal has a silicidation temperature lower than the silicidation temperature of the silicide compound of the first metal.

By adopting this configuration, it is possible to form the second silicide film of the gate electrode at a lower temperature than the silicidation temperature of the silicide compound of the first metal. Because of this, it is possible to prevent abnormal growth and coagulation of the first silicide film during forming of the second silicide film of the gate electrode after forming the first silicide film. As a result, it is possible to prevent high resistance of the impurity diffusion layers of the semiconductor device and increases in junction leakage.

With the semiconductor device of the present invention, it is possible for the whole of the gate electrode to be composed of the second silicide film. In the following, a state where the whole of the gate electrode is composed of the second silicide film is referred to as fully silicided. The semiconductor element may further include a gate insulation film formed between the semiconductor substrate and the gate electrode. As for the fully silicided gate electrode, the gate electrode can be composed of the second silicide film from the surface so as to span a surface making contact with the gate insulation film.

According to the semiconductor device of the present invention, the second silicide film of the gate electrode can be configured from a silicide compound of the second metal that is of a silicidation temperature that is lower than that of the silicide compound of the first metal. It is therefore possible to perform siliciding of the gate electrode at a low temperature using the second metal. Because of this, it is possible to make the film thickness of the second silicide film the desired thickness without the occurrence of abnormal growth in the first silicide film at the impurity diffusion layer. As a result, it is possible for the gate electrode to be fully silicided without influencing the impurity diffusion layers.

In the event of using a semiconductor material such as polysilicon as the gate electrode material, there are cases where a depletion layer occurs in the polysilicon of the gate electrode in the vicinity of the interface with the gate insulation film. When a depletion layer occurs, a sufficient electric field is not applied to the gate insulation film even if a gate voltage is applied, and it is difficult to induce carriers in the channel region. The effect of this is that the threshold voltage is raised and variation in threshold voltages is substantial. According to the present invention, the gate electrode is fully silicided, and the gate electrode does not contain semiconductor so that this kind of problem is therefore resolved.

In the semiconductor device of the present invention, the semiconductor element further includes a gate insulation film containing a film formed between the semiconductor substrate and the gate electrode, containing Hr or Zr, and being in contact with the gate electrode.

Here, the film containing Hf or Zr can be a high dielectric constant insulation film (high-k film). By using the high dielectric constant insulation film as the gate insulation film, it is possible to make Equivalent Oxide Thickness of the gate insulation film thin even if the physical thickness of the gate insulation film is made thick to a certain extent so as to bring about a physically and structurally stable gate insulation film. As a result, the current drive performance of the transistor can be improved and the gate leakage current can be reduced.

However, according to recent research, in the event where the gate insulation film is composed of a high dielectric constant insulation film and the gate electrode is made of polysilicon, it is known that a phenomenon referred to as Fermi Level Pinning occurs (C. Hobbs et al, “Fermi Level Pinning at the PolySi/Metal Oxide Interface”, 2003 Symposium on VLSI Technology Digest of Technical Papers, 4-89114-035-6/03). Fermi level pinning can be considered to be where, in the vicinity of the interface of the side of the gate insulation film within the gate electrode, metal constituting a high dielectric constant insulation film diffuses to within the polysilicon constituting the gate electrode so that levels are formed based on bonds between the silicon and the metal. In particular, in the case of using a film containing Hf or Zr, Fermi level pinning is such that it is easy for a P-type MOSFET having a gate electrode composed of polysilicon containing P-type impurity to occur.

Because of this, in the case where the gate insulation film is constructed of a film containing Hf or Zr, in the vicinity of the interface of the gate insulation film in the gate electrode, it is easy for the kind of depletion layer described above to be generated within the polysilicon. Conventionally, in the event of employing a high dielectric constant insulation film as a gate insulation film, the problems of increase in threshold voltage and variation in the threshold voltage are more prevalent than in the case of using silicon oxide film as the gate insulation film.

However, according to the present invention, at the gate electrode, the second silicide film can be fully silicided and this kind of depletion layer problem can be resolved. As a result, the current drive performance of the transistor can be improved and the gate leakage current can be reduced. In the event that the film contains Hf or Zr and is not a high dielectric constant insulation film, the effect of resolving this depletion layer problem is obtained, and the present invention can be applied to cases where the film is not a high dielectric constant insulation film.

According to the present invention, there is provided a method of manufacturing a semiconductor device, including: preparing a structure comprising a semiconductor element and impurity diffusion layers formed at both sides of a region on which the semiconductor element is formed of the semiconductor substrate, the semiconductor element including a gate electrode composed of polysilicon; forming first silicide films composed of a silicide compound of a first metal at the surface of the impurity diffusion layers; and forming a second silicide film composed of a silicide compound of a second metal different to the first metal at least at the surface of the polysilicon of the gate electrode, wherein, in the forming the second silicide film, the second silicide film is formed under lower temperature conditions than the temperature used in the forming the first silicide film.

In this way, the second silicide film of the gate electrode is formed under temperature conditions that are lower than the forming of the first silicide film. Therefore, for example, in the event that the second silicide film is formed in a separate process after forming the first silicide film at the surface of the impurity diffusion layer, it is possible to form the second silicide film at a low temperature. Because of this, it is possible to prevent abnormal growth and coagulation of the first silicide film during forming of the second silicide film of the gate electrode after forming the first silicide film. As a result, it is possible to prevent high resistance of the impurity diffusion layers of the semiconductor device and increases in junction leakage.

In the manufacturing method of the present invention, the forming the first silicide film may include: forming a film of the first metal on the entire surface of the semiconductor substrate in such a manner as to be in contact with the impurity diffusion layers; and siliciding the surface of the impurity diffusion layers by carrying out heat treatment under a first temperature condition. The forming the second silicide film may also include: forming a film of the second metal on the entire surface of the semiconductor substrate in such a manner as to be in contact with the polysilicon of the gate insulation film; and siliciding at least the surface of the polysilicon by carrying out heat treatment under a second temperature condition lower than the first temperature condition.

In this way, in the forming of the second silicide film, by making the second temperature condition low, after forming the first silicide film it is possible to prevent abnormal growth and coagulation of the first silicide film during forming of the second silicide film of the gate electrode. As a result, it is possible to prevent high resistance of the impurity diffusion layers of the semiconductor device and increases in junction leakage.

In the method of manufacturing a semiconductor device of the present invention, in the forming of the second silicide film, it is possible to make the second temperature condition a temperature condition lower than the silicidation temperature of the silicide compound of the first metal.

In this way, by making the second temperature condition a lower temperature than the silicidation temperature of the silicide compound of the first metal, after forming the first silicide film, it is possible to prevent abnormal growth and coagulation of the first silicide film during forming of the second silicide film of the gate electrode. As a result, it is possible to prevent high resistance of the impurity diffusion layers of the semiconductor device and increases in junction leakage.

According to the present invention, in the semiconductor device with a silicide film formed at the gate electrode and impurity diffusion layers, it is possible to suppress abnormal growth and coagulation of the silicide film of the impurity diffusion layers.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view showing a configuration for a semiconductor device of an embodiment of the present invention.

FIGS. 2A to 2C are cross-sectional views of steps showing a manufacturing procedure for a semiconductor device of the embodiment of the present invention.

FIGS. 3A and 3B are cross-sectional views of steps showing a manufacturing procedure for a semiconductor device of the embodiment of the present invention.

FIGS. 4A to 4C are cross-sectional views of steps showing a manufacturing procedure for a semiconductor device of the embodiment of the present invention.

FIGS. 5A to 5C are cross-sectional views of steps showing a manufacturing procedure for a semiconductor device of a further embodiment of the present invention.

FIGS. 6A to 6C are cross-sectional views of steps showing a manufacturing procedure for a semiconductor device of another embodiment of the present invention.

FIGS. 7A and 7B are cross-sectional views of steps showing a manufacturing procedure for a semiconductor device of the other embodiment of the present invention.

FIGS. 8A to 8C are cross-sectional views of steps showing a manufacturing procedure for a semiconductor device of the other embodiment of the present invention.

FIG. 9 is a cross-sectional view showing a configuration for a semiconductor device of a still further embodiment of the present invention.

FIGS. 10A to 10C are cross-sectional views of steps showing a manufacturing procedure for a semiconductor device of the still further embodiment of the present invention.

FIG. 11 is another cross-sectional view showing a configuration for a semiconductor device of the still further embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

The following is a description of a preferred embodiment of the present invention. The description is given using the drawings. In all of the drawings, the same elements of the configuration are given the same numerals and descriptions thereof are not repeated.

### First Embodiment

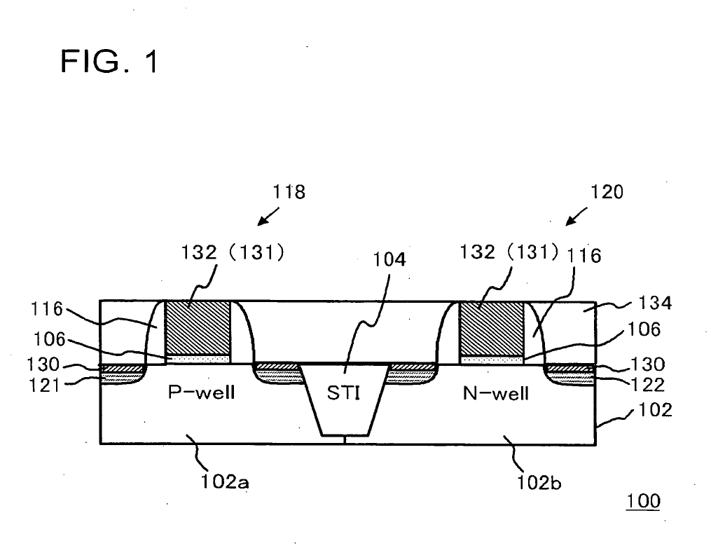

FIG. 1 is a cross-sectional view showing a configuration for a semiconductor device of this embodiment. In this embodiment, semiconductor device 100 is a CMOS (Complementary Metal Oxide Semiconductor) device containing an N-type MOSFET 118 and a P-type MOSFET 120. Further, this CMOS device constitutes the internal circuit of an LSI.

The semiconductor device 100 contains a silicon substrate 102 provided with a P-well 102a of a P-type conductor and an N-well 102b of an N-type conductor, and an element isolation region 104 for isolating the P-well 102a and the N-well 102b. The N-type MOSFET 118 and the P-type MOSFET 120 are formed at the P-well 102a and the N-well 102b, respectively. An inter-layer insulation film 134 covering the side of the N-type MOSFET 118 and the P-type MOSFET 120 is formed on the silicon substrate 102.

A pair of impurity diffusion layers 121 is provided at the P-well 102a, with a channel region being formed between these impurity diffusion layers 121. A gate (semiconductor element) constructed from a gate insulation film 106, a gate electrode 132 provided on the gate insulation film 106, and a sidewall insulation film 116 is provided on the channel region. Similarly, a pair of impurity diffusion layers 122 is provided at the N-well 102b, with a channel region being formed between these impurity diffusion layers 122. A gate constructed from a gate insulation film 106, a gate electrode 132 provided on the gate insulation film 106, and a sidewall insulation film 116 is provided on the channel region.

First silicide films 130 constituted of a silicide compound of a first metal is formed at the surfaces of the impurity diffusion layers 121 and the impurity diffusion layers 122. In this embodiment, the gate electrode 132 contains a second silicide film 131 composed of a silicide compound of a second metal, where the silicidation temperature of which is lower than that of the silicide compound of the first metal. Here, the combination of the first metal and the second metal may be, in this order, nickel and palladium, cobalt and palladium, or cobalt and nickel. The silicidation temperature of the cobalt silicide compound (CoSi₂) is approximately 550 to 600 degrees centigrade, the silicidation temperature of the nickel silicide compound (NiSi) is approximately 400 to 500 degrees centigrade, and the silicidation temperature of the palladium silicide compound (Pd₂Si) is approximately 300 degrees centigrade (Kusano, Sano, or S. S. Lau et al.) In this embodiment, as will be described in the following, after forming the first silicide film 130 on the impurity diffusion layers 121 and the impurity diffusion layers 122, the second silicide film 131 of the gate electrode 132 is formed in a step separate from this. The second silicide film 131 is made from the silicide compound of the second metal whose silicidation temperature is lower than that of the silicide compound of the first metal. The second silicide film 131 can therefore be formed at a lower temperature than the silicidation temperature of the silicide compound of the first metal of the first silicide film 130. Because of this, it is possible to prevent abnormal growth and coagulation of the first silicide film 130 during formation of the second silicide film 131 of the gate electrode 132 after forming the first silicide film 130.

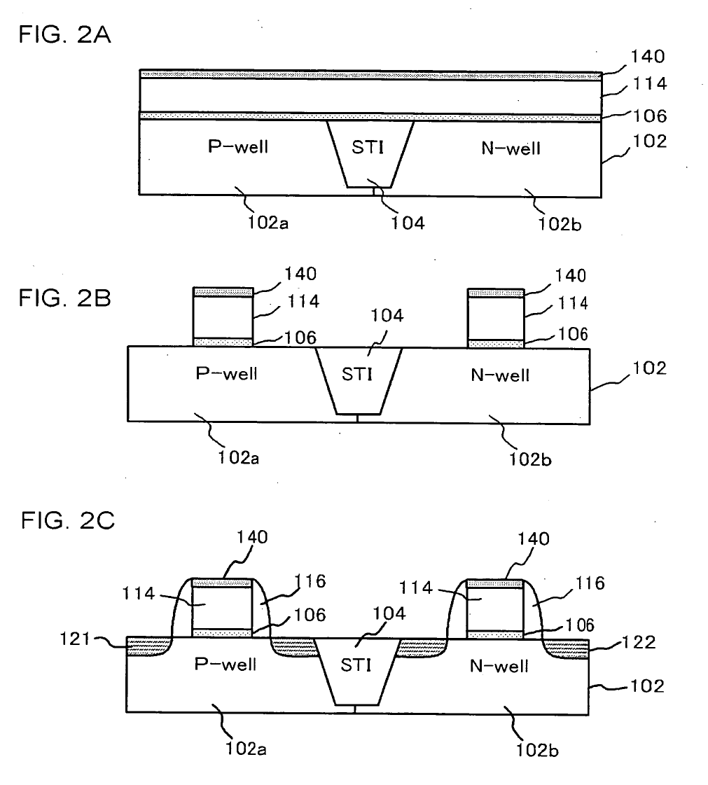

The following is a description with reference to FIGS. 2A to 2C, 3A, 3B, and 4A to 4C of a method for manufacturing the semiconductor device of this embodiment.

FIGS. 2A to 2C, 3A, 3B, and 4A to 4C are cross-sectional views of processes showing a procedure for manufacturing the semiconductor device 100 of this embodiment.

First, after forming the element isolation region 104 at the silicon substrate 102 using, for example, STI (Shallow Trench Isolation), a P-well 102a is formed by ion implantation of a P-type impurity, and an N-well 102b is formed by ion implantation of an N-type impurity. The element isolation region 104 may also be formed using other well-known methods such as, for example, LOCOS techniques, etc. Continuing on, channel regions are formed at the P-well 102a and the N-well 102b using well-known technology. A punch-through stopper region may be formed by ion implantation of N-type impurity and P-type impurity below the channel regions of the P-well 102a and the N-well 102b, respectively. It is possible to suppress the short channel effect by forming this kind of punch-through stopper region.

Next, the gate insulation film 106 is formed on the surface of the silicon substrate 102. Here, the gate insulation film 106 may be formed, for example, from a silicon oxide film (of a film thickness of, for example, approximately 1 nm to 2 nm) formed by subjecting the surface of the silicon substrate 102 to thermal oxidation.

After this, a polysilicon film 114 (of a film thickness of, for example, approximately 5 nm to 15 nm) is formed on the gate insulation film 106. Continuing on, a protective film 140 (of a film thickness of, for example, 3 nm to 10 nm) is formed on the polysilicon film 114. Any configuration can be taken for the protective film 140 provided that the protective film 140 function as a hard mask preventing siliciding the polysilicon film 114 during siliciding of the impurity diffusion layers of the surface of the silicon substrate 102 in the subsequent step. The protective film 140 may be a silicon nitride film formed by, for example, CVD (Chemical vapor deposition). In this way, it is possible to obtain the structure shown in FIG. 2A.

Next, selective etching is performed to form the shape of the gate in such a manner that predetermined regions of the gate insulation film 106, the polysilicon film 114 and the protective film 140 remain are left (FIG. 2B).

After this, on the P-well 102a and the N-well 102b, sidewall insulation films 116 are formed respectively at the sidewalls of the gate insulation film 106, the polysilicon film 114, and the protective film 140. The sidewall insulation film 116 can be formed by, for example, anisotropic etching using fluorocarbon gas, etc. Continuing on, on the P-well 102a, the surface layer of the P-well 102a is doped with N-type impurity such as P and As etc. using the gate electrode and the sidewall insulation film 116 as a mask so as to form the impurity diffusion layers 121. Further, on the N-well 102b, the surface layer of the N-well 102b is doped with P-type impurity such as B and BF₂ etc. using the gate electrode and the sidewall insulation film 116 as a mask so as to form the impurity diffusion layers 122. In this way, the source region and the drain region are formed. After this, activation of the impurities is carried out by performing heat treatment in a non-oxidation atmosphere (FIG. 2C).

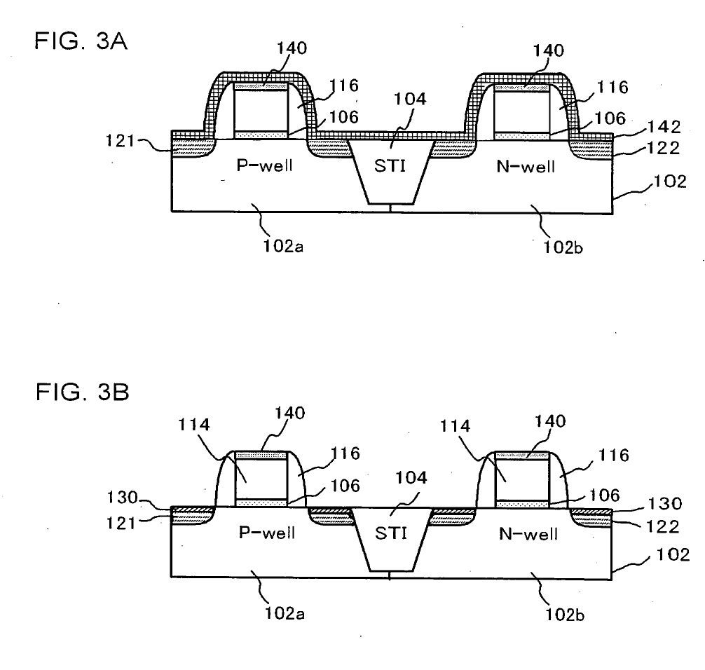

Next, a first metal layer 142 (of a film thickness of, for example, 5 nm to 10 nm) is formed over the whole surface on the silicon substrate 102 (FIG. 3A) using sputtering techniques, etc. Here, the first metal can be taken to be, for example, nickel. After this, the following first heat treatment (sintering) is carried out.

(a-1) Ramp annealing is carried out for approximately 30 seconds at a temperature of approximately 450 degrees centigrade.

(a-2) Unconverted first metal layer 142 is removed by wet etching.

From the above processing, the first silicide film 130 (of a film thickness of, for example, 10 nm to 20 nm) is formed on the surface of the impurity diffusion layers 121 and the impurity diffusion layers 122 (FIG. 3B). At this time, the protective film 140 is provided on the polysilicon film 114 and a silicide layer is therefore not formed on the polysilicon film 114.

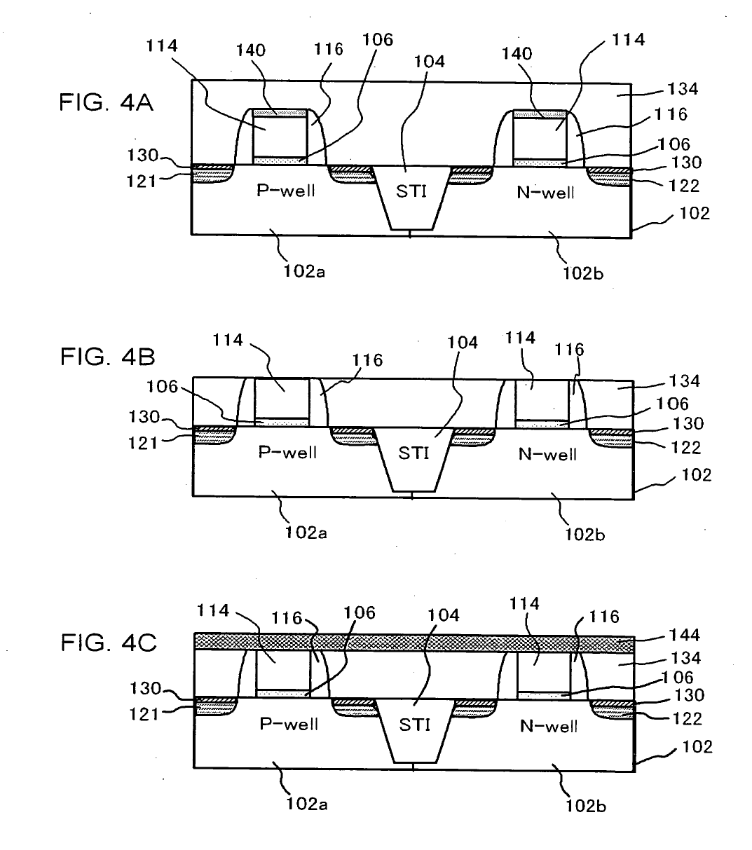

To continue, the inter-layer insulation film 134 is formed on the whole of the surface of the silicon substrate 102 so as to bury the protective film 140 (FIG. 4A). Here, the inter-layer insulation film 134 can be taken to be, for example, a silicon oxide film. Alternatively, the inter-layer insulation film 134 may be a multi-layered film of a silicon nitride film formed on the silicon substrate 102 and a silicon oxide film formed thereon.

Next, the upper part of the inter-layer insulation film 134 and the protective film 140 are removed by CMP (chemical mechanical polishing) and the polysilicon film 114 is exposed (FIG. 4B). After this, a second metal layer 144 (of a film thickness of, for example, approximately 10 nm to 30 nm) is formed on the inter-layer insulation film 134 (FIG. 4C). Here, the second metal can be taken to be, for example, palladium. After this, the following second heat treatment (sintering) is carried out.

(b-1) Ramp annealing is carried out for approximately ten minutes at a temperature of approximately 300 degrees centigrade.

(b-2) Unconverted second metal layer 144 is removed by wet etching.

In the above processing, the whole of the polysilicon film 114 is fully silicided by the second metal layer 144 and the gate electrode 132 is formed. Here, fully silicided means a state where the whole of the gate electrode 132 is constituted by the second silicide film 131. Namely, this means that the polysilicon film 114 is substantially 100% silicided, and the silicon cannot be observed. Here, the gate insulation film 106 is directly in contact with the second silicide film 131. The semiconductor device 100 of the configuration shown in FIG. 1 is formed as a result of the above procedure.

The semiconductor device is formed in which the polysilicon film 114 is silicided in accordance with the second heat treatment condition above. Then, the cross section of the gate electrode 132 of the semiconductor device is observed by a TEM (Transmission Electron Microscope). As the result, it is confirmed that the polysilicon film 114 is fully silicided and silicon cannot be observed.

According to the method of manufacturing the semiconductor device 100 of this embodiment, after forming the first silicide film 130, the heat treatment during siliciding of the polysilicon film 114 is carried out at a temperature lower than the silicidation temperature of the first metal constituting the first silicide film 130. Because of this, it is possible to prevent abnormal growth and coagulation of the first silicide film 130. As a result, it is possible to prevent high resistance of the impurity diffusion layers 121 and impurity diffusion layers 122 of the semiconductor device 100 and increases in junction leakage. Moreover, as the gate 132 is fully silicided, it is possible to prevent the occurrence of depletion layers at the gate electrode 132 and prevent rising of the threshold voltage and variation in threshold voltages.

In the above example, an example is shown where the first metal is nickel and the second metal is palladium but other examples such as the first metal of cobalt and the second metal of palladium, or the first metal of cobalt and the second metal of nickel, are also possible. The conditions for heat treatment in each case may be, for example, as shown in the following.

(i) In the case where the first metal is cobalt and the second metal is palladium:

The first heat treatment may be as shown in the following.

(a-1) Ramp annealing is carried out for approximately 30 seconds at a temperature of approximately 600 degrees centigrade;

(a-2) Unconverted first metal layer 142 is removed by wet etching.

The second heat treatment may be as shown in the following.

(b-1) Ramp annealing is carried out for approximately ten minutes at a temperature of approximately 300 degrees centigrade.

(b-2) Unconverted second metal layer 144 is removed by wet etching.

(ii) In the case where the first metal is cobalt and the second metal is nickel:

The first heat treatment may be as shown in the following.

(a-1) Ramp annealing is carried out for approximately 30 seconds at a temperature of approximately 600 degrees centigrade.

(a-2) Unconverted first metal layer 142 is removed by wet etching.

The second heat treatment may be as shown in the following:

(b-1) Ramp annealing is carried out for approximately 60 seconds at a temperature of approximately 450 degrees centigrade.

(b-2) Unconverted second metal layer 144 is removed by wet etching.

In the above, by using a metal of a silicidation temperature that is lower than the silicidation temperature of the first metal constituting the first silicide film 130 as the second metal constituting the gate electrode 132, it is possible to make the heat treatment temperature during siliciding of the gate electrode 132 lower. As a result, it is possible to suppress abnormal growth and coagulation of the previously formed first silicide film 130 at the impurity diffusion layers 121 and the impurity diffusion layers 122. It is therefore possible to prevent high resistance of the impurity diffusion layers 121 and the impurity diffusion layers 122 of the semiconductor device 100 and increases in junction leakage. Moreover, it is therefore possible to make the gate electrode 132 fully silicided without carrying out high-temperature heat treatment because the silicidation temperature of the second metal is low. Because of this, it is possible to prevent the occurrence of depletion layers at the gate electrode 132 and prevent rising of the threshold voltage and variation in threshold voltages.

### Second Embodiment

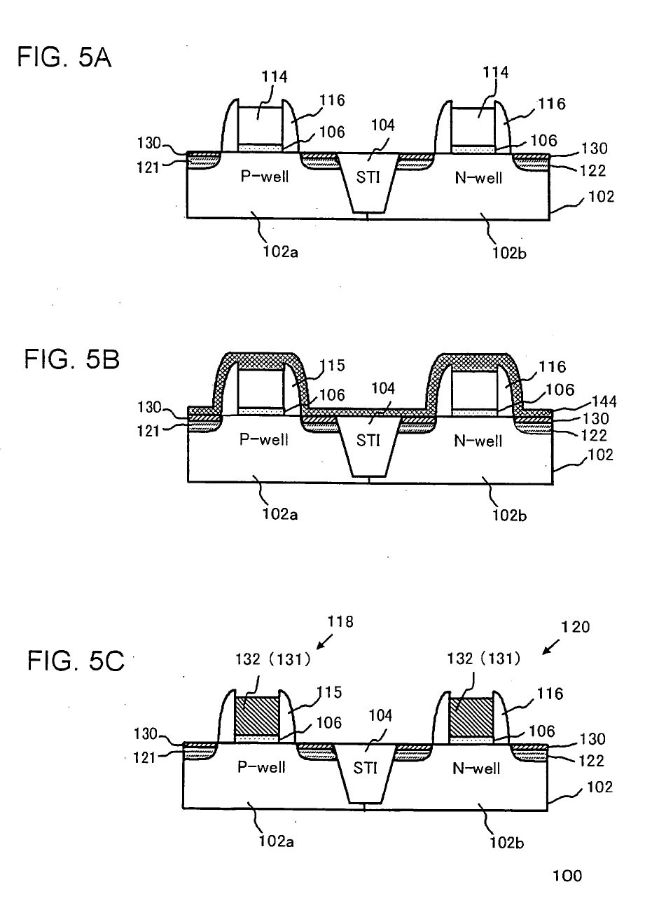

In this embodiment, part of the procedure for manufacturing the semiconductor device 100 is different to the first embodiment. The following is a description with reference to FIGS. 5A to 5C of a method for manufacturing a semiconductor device of this embodiment. FIGS. 5A to 5C are cross-sectional views of processes showing part of a procedure for manufacturing the semiconductor device 100 of this embodiment.

In this embodiment also, a structure that is the same as the structure shown in FIG. 3B is formed using the same procedure described with reference to FIGS. 2A to 2C, 3A and 3B in the first embodiment. The protective film 140 is selectively removed by, for example, dry etching, and the polysilicon film 114 is exposed (FIG. 5A).

Next, the second metal layer 144 (of a film thickness of, for example, 5 nm to 10 nm) is formed over the whole surface on the silicon substrate 102 (FIG. 5B). After this, second heat treatment is carried out. The metal composing the second metal layer 144 and the conditions for the second heat treatment are the same as described for the first embodiment.

In the above processing, the polysilicon film 114 is fully silicided by the second metal layer 144 and gate electrode 132 is formed. Continuing on, unconverted second metal layer 144 is then removed by wet etching, and the semiconductor device 100 of this embodiment is obtained (FIG. 5C).

In this embodiment, it is possible to obtain the same effects as for the first embodiment. This makes it possible to simplify the manufacturing process for the semiconductor device 100.

### Third Embodiment

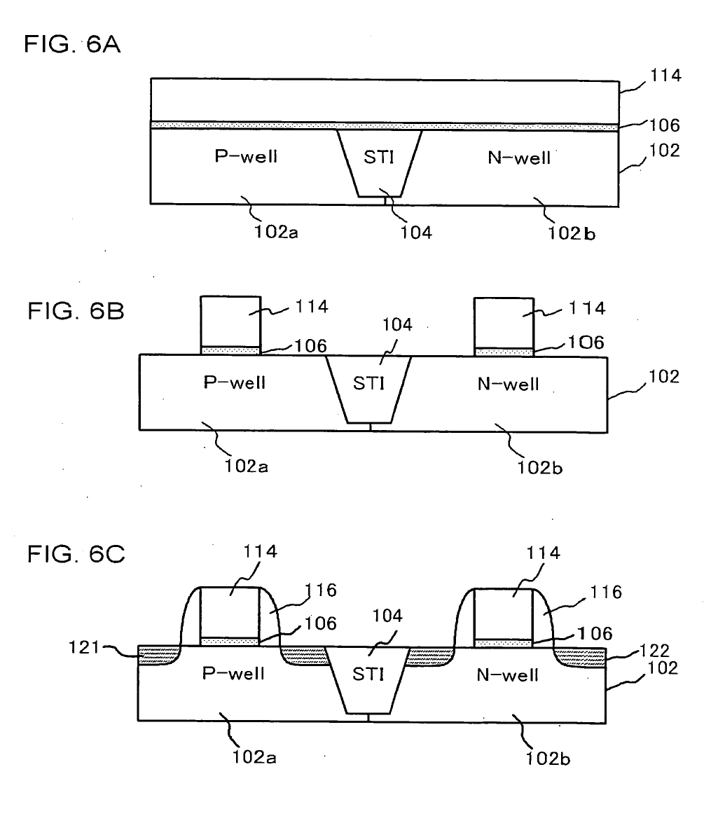

In this embodiment, part of the procedure for manufacturing the semiconductor device 100 is different to the first embodiment. The following is a description with reference to FIGS. 6A to 6C, 7A, 7B and 8A to 8C of a method for manufacturing a semiconductor device of this embodiment. FIGS. 6A to 6C, 7A, 7B and 8A to 8C are cross-sectional views of processes showing part of a procedure for manufacturing the semiconductor device 100 of this embodiment.

First, as described in the first embodiment, the element isolation region 104, the P-well 102a, and the N-well 102b are formed on the silicon substrate 102, and the gate insulation film 106 and the polysilicon film 114 are formed on the silicon substrate 102 (FIG. 6A). This embodiment differs from the first embodiment in that a protective film 140 is not formed on the polysilicon film 114.

Next, selective etching is performed to form the gate shape in such a manner that predetermined regions of the gate insulation film 106 and the polysilicon film 114 are left (FIG. 6B).

Next, on the P-well 102a and the N-well 102b, sidewall insulation films are formed respectively at the sidewalls of the gate insulation film 106 and the polysilicon film 114. After this, on the P-well 102a, the surface layer of the P-well 102a is doped with N-type impurity such as P and As etc. using the gate electrode and the sidewall insulation film 116 as a mask so as to form the impurity diffusion layers 121. Further, on the N-well 102b, the surface layer of the N-well 102b is doped with P-type impurity such as B and BF₂ etc. using the gate electrode and the sidewall insulation film 116 as a mask so as to form the impurity diffusion layers 122 (FIG. 6C).

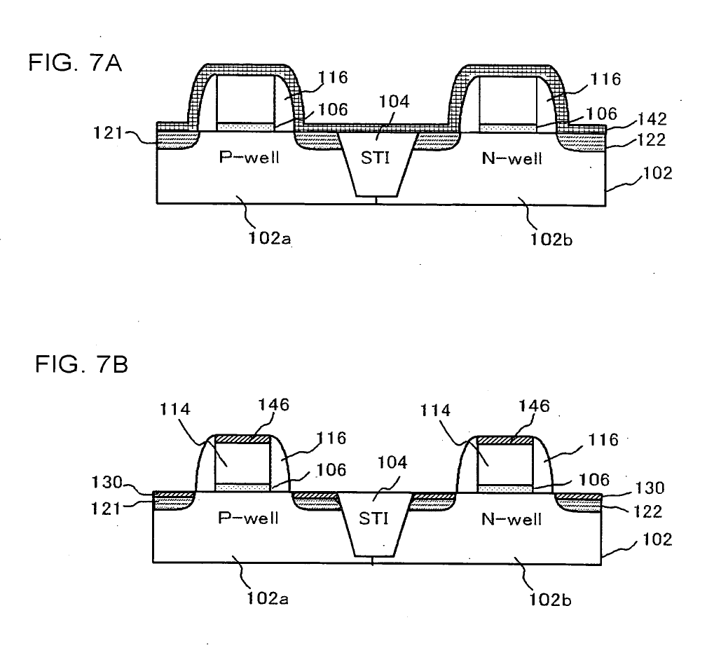

Next, a first metal layer 142 (of a film thickness of, for example, 5 nm to 10 nm) is formed over the whole surface on the silicon substrate 102 (FIG. 7A) using sputtering techniques, etc. The first heat treatment is then carried out. As a result, the first silicide film 130 is formed at the surface of the impurity diffusion layers 121 and the impurity diffusion layers 122, and a silicide film 146 (of a film thickness of, for example, 10 nm to 20 nm) is formed at the surface of the polysilicon film 114 (FIG. 7B).

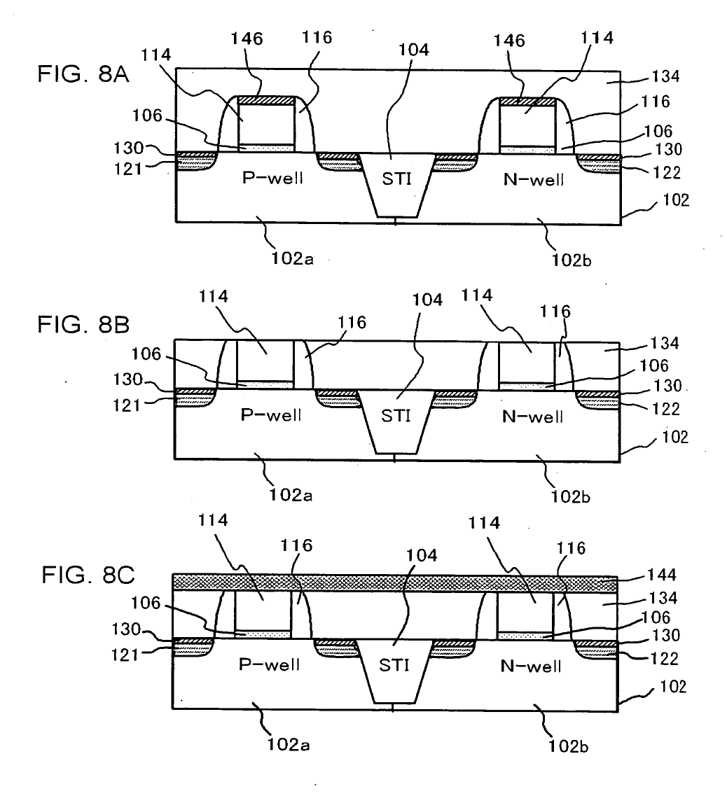

Next, the inter-layer insulation film 134 is formed on the whole of the surface of the silicon substrate 102 so as to bury the silicide film 146 (FIG. 8A). After this, the upper part of the inter-layer insulation film 134 and the silicide film 146 are removed by CMP and the polysilicon film 114 is exposed (FIG. 8B). Next, a second metal layer 144 is formed on the inter-layer insulation film 134. The second heat treatment is then carried out. In this embodiment, the metal constituting the first metal layer 142, the first heat treatment conditions, the metal constituting the second metal layer 144, and the second heat treatment conditions can be made the same as described for the first embodiment.

In the above processing, the polysilicon film 114 is fully silicided by the second metal layer 144 and the gate electrode 132 is formed. As a result, the semiconductor device 100 of the same configuration as shown in FIG. 1 for the first embodiment can also be formed in this embodiment.

In this embodiment, it is possible to obtain the same effects as for the first embodiment. This makes it possible to simplify the manufacturing process for the semiconductor device 100.

### Fourth Embodiment

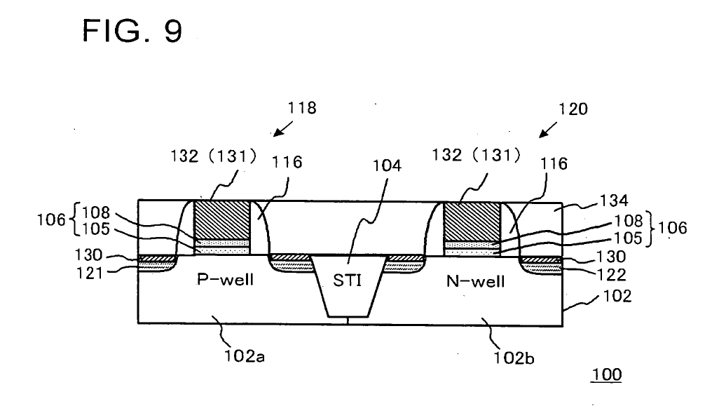

This embodiment differs from the first embodiment in that the gate insulation film 106 is constituted from a multi-layered film. The following is a description with reference to FIG. 9 of a structure for the semiconductor device of this embodiment. FIG. 9 is across-sectional view showing a structure for the semiconductor device 100 of this embodiment. In this embodiment also, the gate insulation film 106 contains a multi-layered film of the silicon oxide film 105 and the high dielectric constant insulation film 108 stacked in this order.

The high dielectric constant insulation film 108 is a film having a higher relative dielectric constant than the silicon oxide film 105 and may be a so-called “high-k film”. For example, the high dielectric constant insulation film 108 may be constructed from a material of a relative dielectric constant of 10 or more. Specifically, the high dielectric constant insulation film 108 may be made from a compound of one or two or more elements selected from a group of Hf and Zr and one or two or more elements selected from a group of Si, O and N. The high dielectric constant insulation film 108 may be composed of, for example, HfSiO or HfAlO, or a nitride thereof. By using this kind of material, it is possible to make the relative dielectric constant of the high dielectric constant insulation film 108 high and to bring about superior heat resistance. Because of this, the size of the MOSFET can be reduced and reliability can be improved. The N-type MOSFEF 118 and the P-type MOSFET 120 can be composed of the same material as the high dielectric constant insulation film 108 or may be composed of different material.

The gate insulation film 106 can be given a configuration that does not have the silicon oxide film 105. However, metal included in the high dielectric constant insulation film 108 can be prevented from diffusing etc. to the silicon substrate 102 by providing the silicon oxide film 105 between the high dielectric constant insulation film 108 and the silicon substrate 102. Further, the silicon oxide film 105 may contain nitrogen.

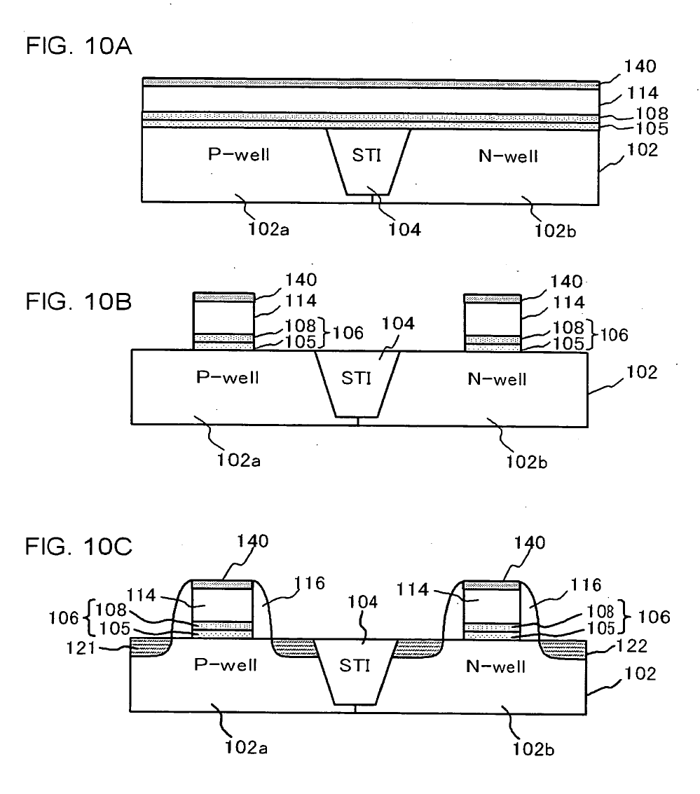

The following is a description with reference to FIG. 10 of a method for manufacturing a semiconductor device of this embodiment. FIGS. 10A to 10C are cross-sectional views of processes showing part of a procedure for manufacturing the semiconductor device 100 of this embodiment.

In this embodiment, first, as described in the first embodiment, the element isolation region 104, the P-well 102a and the N-well 102b are formed on the silicon substrate 102 as described in the first embodiment. Next, the silicon oxide film 105 is formed on the silicon substrate 102. Continuing on, the high dielectric constant insulation film 108 (of a film thickness of, for example, approximately 1 nm) is formed on the silicon oxide film 105. The high dielectric constant insulation film 108 may be formed using CVD techniques or ALD techniques (Atomic Layer Deposition techniques) etc. After this, annealing is carried out using gas containing nitrogen such as, for example, ammonia, etc. A treatment temperature of 900 to 1000 degrees centigrade and a treatment time of 40 seconds etc. are adopted as conditions. It is then possible to suppress crystallization of the high dielectric constant insulation film 108 by carrying out this annealing.

Continuing on, the polysilicon film 114 and the protective film 140 are formed on the high dielectric constant insulation film 108 (FIG. 10A).

Next, the silicon oxide film 105, the high dielectric constant insulation film 108, the polysilicon film 114 and the protective film 140 are selectively dry etched to form the gate shape (FIG. 10B).

Next, on the P-well 102a and the N-well 102b, sidewall insulation films are formed respectively at the sidewalls of the silicon oxide film 105, the high dielectric constant insulation film 108, the polysilicon film 114, and the protective film 140. After this, the impurity diffusion layers 121 are formed on the P-well 102a and the impurity diffusion layers 122 are formed on the N-well 102b (FIG. 10C).

After this, as described for the first embodiment, the first silicide film 130 is formed on the surface of the impurity diffusion layers 121 and the impurity diffusion layers 122. Next, after the inter-layer insulation film 134 is formed on the silicon substrate 102, and the polysilicon film 114 is exposed using CMP, the polysilicon film 114 is fully silicided by the second silicide film and the gate electrode 132 is formed. The semiconductor device 100 of the configuration shown in FIG. 9 is formed as a result.

In this embodiment, it is possible to obtain the same effects as for the first embodiment. Further, as described above, in the event of using the high dielectric constant insulation film 108 as the gate insulation film 106, a so-called “Fermi level pinning” phenomenon occurs, and in the event that the gate electrode 132 is configured using polysilicon film 114, a problem occurs where a depletion layer occurs at the polysilicon film 114. However, in this embodiment, the gate electrode 132 is fully silicided. It is therefore possible to prevent the occurrence of a depletion layer at the gate electrode 132, and it is possible to obtain the benefits of improved current drive performance of the transistor and reduced leakage current as a result of using the high dielectric constant insulation film 108.

In this embodiment also, as described for the third embodiment, it is possible to remove the silicide film 146 afterwards when the process in which the protective film 140 is not formed on the polysilicon film 114 and the silicide film 146 is formed on the surface of the polysilicon film 114 during forming of the first silicide film 130 is used. It is therefore also possible to obtain the semiconductor device 100 of the same configuration as shown in FIG. 9.

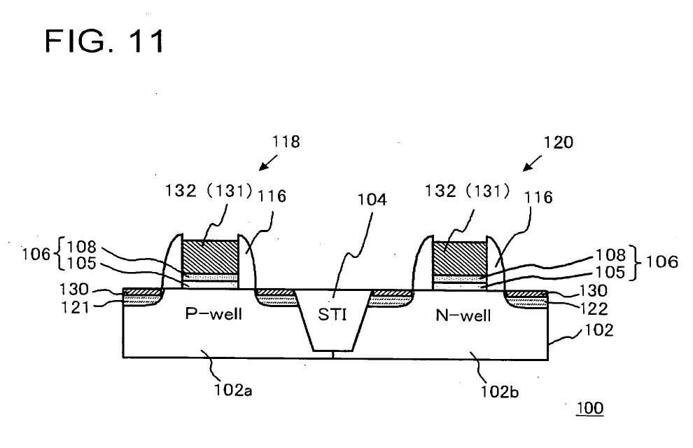

In this embodiment, as described for the second embodiment, after the protective film 140 is formed on the polysilicon film 114 and the first silicide film 130 is formed, it is possible to selectively remove the protective film 140 by etching. The semiconductor device 100 of the configuration shown in FIG. 11 is obtained as a result.

In the above, a description is given of embodiments and practical examples of the present invention with reference to the drawings but this merely illustrates examples of the present invention, and various other configurations can also be adopted.

For example, in the fourth embodiment, a configuration where the high dielectric constant insulation film 108 has a composition including Hr or Zr is shown but the high dielectric constant insulation film 108 is by no means limited in this respect, and configuration using various other well-known materials as so-called high-k films is also possible. Further, in this embodiment, an example is shown of the high dielectric constant insulation film 108 may be a film including Hf or Zr regardless of the relative dielectric constant thereof. Even the film that is not high-k film but includes Hf or Zr is used, an effect of resolving the depletion layer problem is obtained.

Further, in the above embodiments, the gate electrode 132 is shown to be fully silicided but the present invention is also applicable to configurations where the gate electrode 132 is not fully silicided. According to the present invention, the second silicide film 131 is formed in a separate step to the step where the first silicide film 130 is formed and it is possible to form the second silicide film 131 at low temperature. It is therefore possible to make the film thickness of the second silicide film 131 the desired thickness. In this case also, it is also possible to suppress abnormal growth and coagulation of the impurity diffusion layers 121 formed before siliciding of the polysilicon film 114 and first silicide film 130 of the impurity diffusion layers 122. As a result, it is possible to make the film thickness of the second silicide film 131 thick, and to make the resistance of the gate electrode 132 low.

In the event that the polysilicon film 114 is not fully silicided, after forming the polysilicon film 114, it is possible to ion-inject the polysilicon film 114 formed as a film on the P-well 102a with N-type impurity, and ion-implant the polysilicon film 114 formed as a film on the N-well 102b with P-type impurity. This ion implantation may be carried out after forming the polysilicon film 114 and before patterning into an electrode shape, or may be carried out at the same time during forming of the impurity diffusion layers 121 and the impurity diffusion layers 122 after patterning into an electrode shape. Further, it is also possible to carry out similar processing in the event of fully siliciding the polysilicon film 114. However, in this case, the processing of ion implantation of the polysilicon film 114 with impurities can be omitted as well.

Moreover, in the above embodiment, an example is shown where siliciding is carried out by ramp annealing but is it also possible for one or both of the silicide compound of the first metal and the second metal silicide compound to be silicided by furnace annealing. In this event, the second metal silicide compound can be formed under temperature conditions lower than the silicidation temperature of the first siliciding compound.

It is apparent that the present invention is not limited to the above embodiment, and may be modified and changed without departing from the scope and spirit of the invention.

What is claimed is:

1. A semiconductor device comprising:
a semiconductor substrate;
a semiconductor element formed on said semiconductor substrate and containing a gate electrode;
impurity diffusion layers formed at both sides, in a cross-section in a gate length direction of said gate electrode, of a region on which said semiconductor element is formed of said semiconductor substrate;
first silicide films formed respectively at the surface of said impurity diffusion layers, composed of a silicide compound of a first metal; and
a second silicide film, formed at least at the surface of said gate electrode, composed of a silicide compound of a second metal different to said first metal,
wherein said silicide compound of said second metal has a silicidation temperature lower than the silicidation temperature of said silicide compound of said first metal.

2. The semiconductor device according to claim 1,
wherein the combination of said first metal and said second metal is, in order, nickel and palladium, cobalt and palladium, or cobalt and nickel.

3. The semiconductor device according to claim 1,
wherein the whole of said gate electrode is constituted by said second silicide film.

4. The semiconductor device according to claim 2,
wherein the whole of said gate electrode is constituted by said second silicide film.

5. The semiconductor device according to claim 1,
wherein said semiconductor element further includes a gate insulation film formed between said semiconductor substrate and said gate electrode,
wherein said gate insulation film includes a film, containing Hf or Zr, provided so as to be connected to said gate electrode.

6. The semiconductor device according to claim 2,
wherein said semiconductor element further includes a gate insulation film formed between said semiconductor substrate and said gate electrode,
wherein said gate insulation film includes a film, containing Hf or Zr, provided so as to be connected to said gate electrode.

7. The semiconductor device according to claim 3,
wherein said semiconductor element further includes a gate insulation film formed between said semiconductor substrate and said gate electrode,
wherein said gate insulation film includes a film, containing Hf or Zr, provided so as to be connected to said gate electrode.

8. A semiconductor device comprising:
a semiconductor substrate;
a semiconductor element formed on said semiconductor substrate and containing a gate electrode;
impurity diffusion layers formed at both sides, in a cross-section in a gate length direction of said gate electrode, of a region on which said semiconductor element is formed of said semiconductor substrate;
first silicide films formed respectively at the surface of said impurity diffusion layers, composed of a silicide compound of a first metal; and
a second silicide film, formed at least at the surface of said gate electrode, composed of a silicide compound of a second metal different to said first metal,
wherein said silicide compound of said second metal has a silicidation temperature lower than the silicidation temperature of said silicide compound of said first metal.
wherein the combination of said first metal and said second metal is, in order, nickel and palladium, cobalt and palladium, or cobalt and nickel.

9. The semiconductor device according to claim 8,
wherein the whole of said gate electrode is constituted by said second silicide film.

10. The semiconductor device according to claim 8,
wherein said semiconductor element further includes a gate insulation film formed between said semiconductor substrate and said gate electrode,
wherein said gate insulation film includes a film, containing Hf or Zr, provided so as to be connected to said gate electrode.

11. A method of manufacturing a semiconductor device, comprising:
preparing a structure comprising a semiconductor element and impurity diffusion layers formed at both sides of a region on which said semiconductor element is formed of said semiconductor substrate, said semiconductor element including a gate electrode composed of polysilicon;
forming first silicide films composed of a silicide compound of a first metal at the surface of said impurity diffusion layers; and
forming a second silicide film composed of a silicide compound of a second metal different to said first metal at least at the surface of said polysilicon of said gate electrode,
wherein, in said forming the second silicide film, said second silicide film is formed under lower temperature conditions than the temperature used in said forming the first silicide film.

12. The method of manufacturing a semiconductor device according to claim 11,
wherein said forming the first silicide film comprises:
forming a film of said first metal on the entire surface of said semiconductor substrate in such a manner as to be in contact with said impurity diffusion layers; and
siliciding the surface of said impurity diffusion layers by carrying out heat treatment under a first temperature condition, and
wherein said forming the second silicide film comprises:
forming a film of said second metal on the entire surface of said semiconductor substrate in such a manner as to be in contact with said polysilicon of said gate insulation film; and
siliciding at least the surface of said polysilicon by carrying out heat treatment under a second temperature condition lower than said first temperature condition.

13. The method of manufacturing a semiconductor device according to claim 12,
wherein, in said forming the second silicide film, said second temperature condition is a temperature condition lower than the silicidation temperature of said silicide compound of said first metal.

14. The method of manufacturing a semiconductor device according to claim 12,
wherein, in said forming the second silicide film, the whole of said polysilicon film is changed to said second silicide film.

15. The method of manufacturing a semiconductor device according to claim 13,
wherein, in said forming the second silicide film, the whole of said polysilicon film is changed to said second silicide film.

16. The method of manufacturing a semiconductor device according to claim 12, further comprising:
forming a protective film at the surface of said gate electrode before said forming the first silicide film; and
removing said protective film so as to expose said polysilicon of said gate electrode after said forming the first silicide film and before said forming the second silicide film.

17. The method of manufacturing a semiconductor device according to claim 14, further comprising:
forming a protective film at the surface of said gate electrode before said forming the first silicide film; and
removing said protective film so as to expose said polysilicon of said gate electrode after said forming the first silicide film and before said forming the second silicide film.

18. The method of manufacturing a semiconductor device according to claim 16,
further comprising, before said forming the second silicide film,
forming an inter-layer insulation film at the whole of the surface of said semiconductor substrate in such a manner as to bury said protective film,
wherein said removing the protective film, said inter-layer insulation film and said protective film are removed by planarization to expose said polysilicon of said gate electrode.

19. The method of manufacturing a semiconductor device according to claim 17,
further comprising, before said forming the second silicide film,
forming an inter-layer insulation film at the whole of the surface of said semiconductor substrate in such a manner as to bury said protective film,
wherein said removing the protective film, said inter-layer insulation film and said protective film are removed by planarization to expose said polysilicon of said gate electrode.
